(19) United States
(12) Patent Application Publication
(10) Pub. No.: US 2024/0170354 A1
(43) Pub. Date: May 23, 2024

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventor: Yasutaka SHIMIZU, Tokyo (JP)

(73) Assignee: Mitsubishi Electric Corporation, Tokyo (JP)

(21) Appl. No.: 18/448,748

(22) Filed: Aug. 11, 2023

(30) Foreign Application Priority Data
Nov. 22, 2022 (JP) 2022-186108

(51) Int. Cl. H01L 23/14; H01L 23/10; H01L 23/498

(52) U.S. Cl. CPC H01L 23/14; H01L 23/10; H01L 23/49811

(57) ABSTRACT

A semiconductor device includes a semiconductor element, a case having an opening and accommodating the semiconductor element, a signal terminal provided on the inner wall of the case, a printed board disposed above the semiconductor element in the case by the signal terminal, and a lid that closes the opening of the case. The semiconductor element and the signal terminal are electrically connected by the wire. The wire is curved upward, and the top portion of the wire is in contact with the back surface of the printed board.

### BACKGROUND OF THE INVENTION

### Field of the Invention

The present disclosure relates to a semiconductor device and a method of manufacturing the semiconductor device.

### Description of the Background Art

A technique has been proposed in which a printed board is disposed above a semiconductor element in a case, and the printed board is supported by a support base molded on the inner wall of the case (see, for example, Japanese Patent Application Laid-Open No. 2000-68446).

In the technique described in Japanese Patent Application Laid-Open No. 2000-68446, a protrusion having a columnar shape and a hemispherical tip is provided inside a lid plate disposed on the upper surface of a case, and the protrusion of the lid plate presses a printed board, thereby alleviating the stress generated at a solder joint between the printed board and a signal terminal.

However, in the technique described in Japanese Patent Application Laid-Open No. 2000-68446, the printed board and the support base are brought into contact with each other by pressing the printed board with the protrusion of the lid plate. Therefore, when the sealing material in the case expands or contracts due to a temperature change, the protrusion of the lid plate acts as a force point, and a portion of the printed board positioned between the protrusion and the support base may be cracked, and there is a concern that the reliability of the semiconductor device may be lowered.

### SUMMARY

An object of the present disclosure is to provide a technique capable of improving the reliability of a semiconductor device by suppressing cracking of a printed board.

A semiconductor device according to the present disclosure includes a semiconductor element, a case, a signal terminal, a printed board, and a lid.

The case has an opening and accommodates the semiconductor element.

The signal terminal is provided on an inner wall of the case.

The printed board is disposed above the semiconductor element in the case by the signal terminal.

The lid closes the opening of the case.

The semiconductor element and the signal terminal are electrically connected by a wire.

The wire is curved upward.

A top portion of the wire is in contact with a back surface of the printed board.

When stress is applied to the signal terminal connected to the printed board due to the vibration of the semiconductor device, the stress applied to the signal terminal is alleviated by the wire in contact with the back surface of the printed board.

Consequently, cracking of the printed board can be suppressed, so that the reliability of the semiconductor device can be improved.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a cross-sectional view of a semiconductor device according to a first preferred embodiment;

FIG. 2 is a cross-sectional view of a semiconductor device according to a first modification of the first preferred embodiment;

FIG. 3 is a perspective view illustrating wires included in a semiconductor device according to a second modification of the first preferred embodiment and a portion around the wires; and

FIG. 4 is a cross-sectional view of a semiconductor device according to a second preferred embodiment.

### DESCRIPTION OF THE PREFERRED EMBODIMENTS

### First Preferred Embodiment

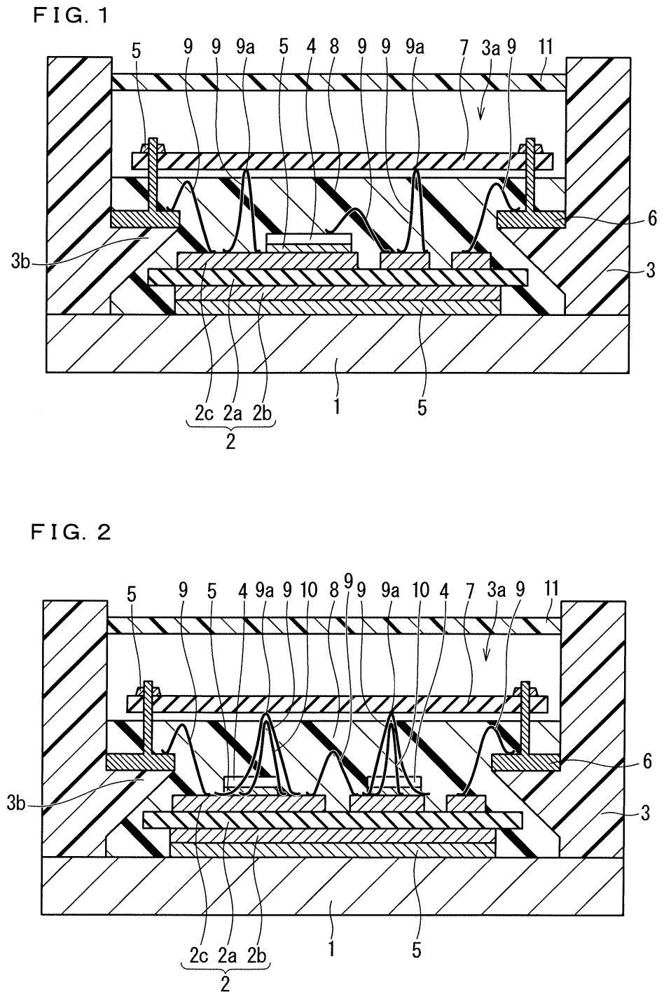

The first preferred embodiment will be described below with reference to the accompanying drawings. FIG. 1 is a cross-sectional view of a semiconductor device according to the first preferred embodiment.

As illustrated in FIG. 1, the semiconductor device includes a base plate 1, an insulating substrate 2, at least one semiconductor element 4, a case 3, a printed board 7, a sealing material 8, a plurality of wires 9, and a lid 11.

The base plate 1 is made of a metal such as copper and is formed in a rectangular shape in top view. The insulating substrate 2 is bonded to a portion of the upper surface of the base plate 1 excluding the outer peripheral portion with a bonding material 5. The insulating substrate 2 includes an insulating base material 2a, a metal layer 2b formed on the lower surface of the insulating base material 2a, and a circuit pattern 2c formed on the upper surface of the insulating base material 2a. The insulating base material 2a is made of ceramic or the like. The metal layer 2b and the circuit pattern 2c are made of a metal such as copper. The bonding material 5 is, for example, a solder.

The case 3 is formed in a rectangular frame shape in top view and is joined to an outer peripheral portion of the base plate 1. The case 3 is made of a resin and has insulating properties. A lower portion of the inner wall of the case 3 is provided with a protruding portion 3b protruding inward. The protruding portion 3b is provided, for example, on the inner wall of the case 3 over the circumferential direction. The protruding portion 3b is provided with a plurality of signal terminals 6 having a shape extending upward.

The semiconductor element 4 is mounted on the upper surface of insulating substrate 2. Specifically, the semiconductor element 4 is bonded to the upper surface of the circuit pattern 2c with the bonding material 5. The semiconductor element 4 is electrically connected to the signal terminal 6 by a plurality of wires 9. Here, the number of semiconductor elements 4 is not limited to one and may be plural.

The semiconductor element 4 is, for example, an insulated gate bipolar transistor (IGBT) or a metal oxide semiconductor field effect transistor (MOSFET). The semiconductor element 4 may include a free wheeling diode (FWD) electrically connected to the semiconductor element 4. The semiconductor element 4 is made of silicon or a wide band gap semiconductor material. The wide band gap semiconductor material is silicon carbide, a gallium nitride-based semiconductor material, diamond, or the like.

The printed board 7 is formed in a rectangular shape in top view and is disposed

above the semiconductor element 4 in the case 3 by the signal terminals 6. Specifically, a through hole (not shown) is formed in a corner portion of the printed board 7, and the upper end portion of the signal terminal 6, among the plurality of signal terminals 6, which is positioned at the corner portion of the printed board 7 is inserted into the through hole and joined to the through hole with the bonding material 5.

The sealing material 8 is, for example, an epoxy resin, and is filled between the base plate 1 and the printed board 7 in the case 3. Specifically, the sealing material 8 is filled below the lower surface of printed board 7, and is not in contact with the printed board 7.

The lid 11 is attached above the printed board 7 in the case 3 so as to close an opening 3a of the case 3. Similarly to the case 3, the lid 11 is made of resin and has insulating properties.

Next, the wire 9 will be described. The wire 9 has a function of supporting the printed board 7 from below in addition to a function of electrically connecting the semiconductor element 4 and the signal terminal 6. The wire 9 is curved upward and has a top portion 9a which is a portion at the highest height position. The top portion 9a of at least one of the plurality of wires 9 comes into contact with the back surface of the printed board 7, so that the wire 9 can support the printed board 7 from below. As a result, when stress is applied to the signal terminal 6 connected to the printed board 7 due to the vibration of the semiconductor device, the stress applied to the signal terminal 6 can be alleviated.

Further, the position of the printed board 7 with which the top portion 9a of the wire 9 is in contact is at the same potential as the wire 9. Here, the wire 9 is an aluminum wire or a copper wire.

As illustrated in FIG. 1, the top portion 9a of each wire 9, among the plurality of wires 9, which is located around the plurality of signal terminals 6 is in contact with the back surface of the printed board 7. As described above, it is desirable that the top portions 9a of the plurality of wires 9 are in contact with the back surface of the printed board 7. However, in a case where there is a signal terminal 6 to which stress is particularly likely to be applied, only the top portion 9a of one wire 9 located around the signal terminal 6 may be in contact with the back surface of the printed board 7.

Although not illustrated, the wire 9 is curved in a corrugated shape and may have a plurality of top portions 9a. In this case, the plurality of top portions 9a of the wire 9 are in contact with the back surface of the printed board 7. Here, the number of the corrugated wires 9 may be one or more.

As described above, the semiconductor device according to the first preferred embodiment includes the semiconductor element 4, the case 3 having the opening 3a and accommodating the semiconductor element 4, the signal terminal 6 provided on the inner wall of the case 3, the printed board 7 disposed above the semiconductor element 4 in the case 3 by the signal terminal 6, and the lid 11 that closes the opening 3a of the case 3. The semiconductor element 4 and the signal terminal 6 are electrically connected by the wire 9. The wire 9 is curved upward, and the top portion 9a of the wire 9 is in contact with the back surface of the printed board 7.

Accordingly, when stress is applied to the signal terminal 6 connected to the printed board 7 due to the vibration of the semiconductor device, the stress applied to the signal terminal 6 is alleviated by the wire 9 in contact with the back surface of the printed board 7. Consequently, cracking of the printed board 7 can be suppressed, so that the reliability of the semiconductor device can be improved.

In addition, since it is not necessary to thicken the printed board 7 for the purpose of suppressing cracking of the printed board 7, it is not necessary to accurately control the dimensions of the printed board 7 and the assembling method.

The semiconductor device includes a plurality of wires 9, and the top portion 9a of each wire 9 is in contact with the back surface of the printed board 7. Accordingly, by supporting the printed board 7 by the plurality of wires 9, the stress applied to the signal terminal 6 can be effectively alleviated as compared with the case of supporting the printed board 7 by one wire 9. Accordingly, further improvement in reliability of the semiconductor device can be achieved.

In addition, the wire 9 is corrugated, and the top portion 9a of the wire 9 is in contact with the back surface of the printed board 7. Therefore, by supporting the printed board 7 by the plurality of top portions 9a, the stress applied to the signal terminal 6 can be effectively alleviated as compared with the case of supporting the printed board 7 at one point. Accordingly, further improvement in reliability of the semiconductor device can be achieved.

Further, since the position of the printed board 7 with which the top portion 9a of the wire 9 is in contact has the same potential as the wire 9, the printed board 7 can be prevented from being electrically affected by the wire 9.

### Modification of First Preferred Embodiment

Next, first and second modifications of the first preferred embodiment will be described. FIG. 2 is a cross-sectional view of a semiconductor device according to a first modification of the first preferred embodiment. As illustrated in FIG. 2, the semiconductor device according to the first modification of the first preferred embodiment may further include a support wire 10. The support wire 10 is curved upward and supports the top portion 9a of the wire 9 from below. Here, the support wire 10 is an aluminum wire or a copper wire.

The semiconductor device according to the first modification of the first preferred embodiment further includes the support wire 10 that supports the top portion 9a of the wire 9 from below, so that it is possible to cope with the stress caused by the large vibration of the semiconductor device without increasing the area for supporting the printed board 7.

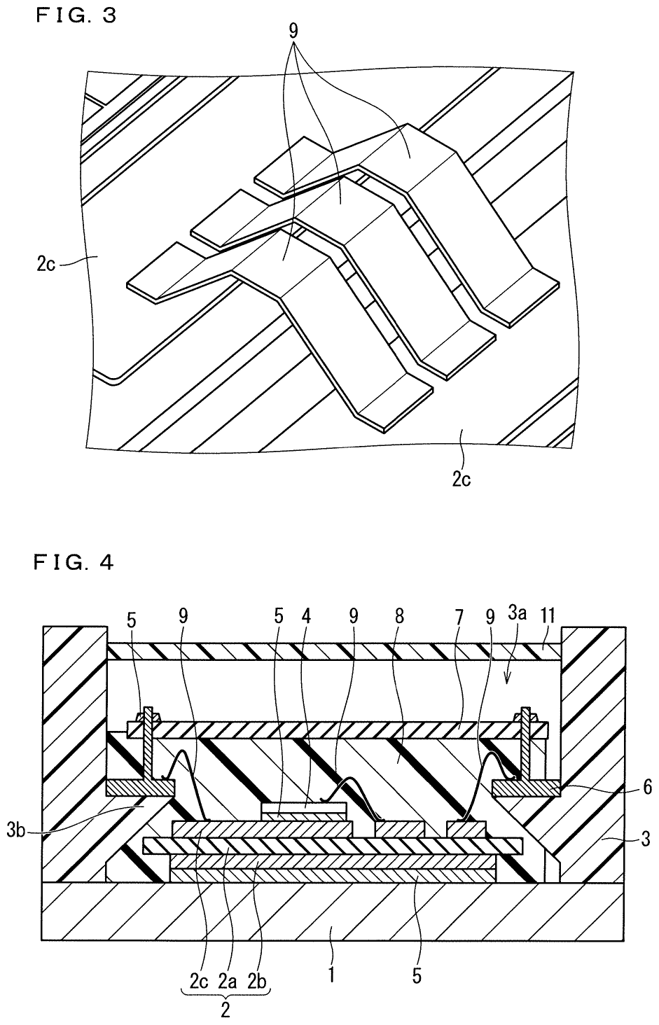

FIG. 3 is a perspective view illustrating wires 9 included in a semiconductor

device according to the second modification of the first preferred embodiment and a portion around the wires 9. As illustrated in FIG. 3, the wire 9 may be a ribbon wire. The ribbon wire is made of aluminum or copper.

In the semiconductor device according to the second modification of the first preferred embodiment, since the wire 9 includes the ribbon wire, the cross-sectional area of the wire 9 increases as compared with the aluminum wire and the copper wire, so that the strength of the wire 9 increases. This makes it possible to cope with the stress caused by large vibration of the semiconductor device.

### Second Preferred Embodiment

Next, a semiconductor device according to the second preferred embodiment will be described. FIG. 4 is a cross-sectional view of a semiconductor device according to the second preferred embodiment. Note that, in the second preferred embodiment, the same components as those described in the first preferred embodiment are denoted by the same reference numerals, and a description thereof will be omitted.

In the first preferred embodiment, the top portion 9a of the wire 9 is in contact with the back surface of the printed board 7 to support the printed board 7. On the other hand, as illustrated in FIG. 4, in the second preferred embodiment, a sealing material 8 is in contact with a printed board 7 to support the printed board 7.

In a case 3, the sealing material 8 is in contact with only the back surface side of the printed board 7 and is filled up to a height position at which the upper surface of the printed board 7 is exposed. Therefore, the sealing material 8 is not in contact with the upper surface side of printed board 7. The top portion 9a of the wire 9 is not in contact with the back surface of the printed board 7.

Next, a method of manufacturing a semiconductor device will be described in comparison with a conventional case. Conventionally, after the case 3 is filled with the sealing material 8, the printed board 7 is attached above a semiconductor element 4 in the case 3. Therefore, sealing material 8 was filled only up to a height position where it does not come into contact with printed board 7.

On the other hand, in the second preferred embodiment, after the printed board 7 is attached above the semiconductor element 4 in the case 3, the case 3 is filled with the sealing material 8 so that the sealing material 8 is at a height position where the sealing material 8 is in contact with the printed board 7. Therefore, the filling amount of the sealing material 8 can be adjusted based on the height position of the actually attached printed board 7.

As described above, the semiconductor device according to the second preferred embodiment includes the semiconductor element 4, the case 3 having an opening 3a and accommodating the semiconductor element 4, a signal terminal 6 provided on the inner wall of the case 3, a printed board 7 disposed above the semiconductor element 4 in the case 3 by the signal terminal 6, a sealing material 8 for sealing the semiconductor element 4 in the case 3, and the lid 11 that closes the opening 3a of the case 3. The sealing material 8 is in contact with the printed board 7.

Accordingly, when stress is applied to the signal terminal 6 connected to the printed board 7 due to the vibration of the semiconductor device, the stress applied to the signal terminal 6 is alleviated by the sealing material 8 in contact with the printed board 7. Consequently, cracking of the printed board 7 can be suppressed, so that the reliability of the semiconductor device can be improved.

In addition, the sealing material 8 is in contact with only the back surface side of the printed board 7. Therefore, by covering one side of the vibrating printed board 7 with the sealing material 8, the vibration can be suppressed, and stress can be suppressed from being applied to the signal terminal 6 and a bonding material 5 that bonds the printed board 7 and the signal terminal 6.

In the method of manufacturing the semiconductor device according to the second preferred embodiment, the printed board 7 is mounted above the semiconductor element 4 in the case 3, and then the case 3 is filled with the sealing material 8.

Accordingly, since the filling amount of the sealing material 8 can be adjusted based on the height position of the actually attached printed board 7, the filling amount of the sealing material 8 can be easily adjusted so that the sealing material 8 is at the height position where it come into contact with the printed board 7.

Note that the respective preferred embodiments can be freely combined and can be modified and omitted as needed.

Hereinafter, various aspects of the present disclosure will be collectively described as appendixes.

### (Appendix 1)

A semiconductor device comprising:
a semiconductor element;
a case having an opening and accommodating the semiconductor element;
a signal terminal provided on an inner wall of the case;
a printed board disposed above the semiconductor element in the case by the signal terminal; and
a lid that closes the opening of the case,
wherein the semiconductor element and the signal terminal are electrically connected by a wire,
the wire is curved upward, and
a top portion of the wire is in contact with a back surface of the printed board.

### (Appendix 2)

The semiconductor device according to Appendix 1, wherein
the semiconductor device comprises a plurality of the wires, and
the top portion of each of the wires is in contact with the back surface of the printed board.

### (Appendix 3)

The semiconductor device according to Appendix 1 or 2, wherein
the wire is curved in corrugated shape, and
the plurality of top portions of the wire are in contact with the back surface of the printed board.

### (Appendix 4)

The semiconductor device according to any one of Appendixes 1 to 3, further comprising a support wire that supports the top portion of the wire from below.

### (Appendix 5)

The semiconductor device according to any one of Appendixes 1 to 4, wherein a portion of the printed board with which the top portion of the wire is in contact has a same potential as the wire.

### (Appendix 6)

The semiconductor device according to Appendix 1 or 2, wherein the wire includes a ribbon wire.

### (Appendix 7)

A semiconductor device comprising:
a semiconductor element;
a case having an opening and accommodating the semiconductor element;
a signal terminal provided on an inner wall of the case;
a printed board disposed above the semiconductor element in the case by the signal terminal;
a sealing material that seals the semiconductor element in the case; and
a lid that closes the opening of the case,
wherein the sealing material is in contact with the printed board.

### (Appendix 8)

The semiconductor device according to Appendix 7, wherein the sealing material is in contact with only a back surface side of the printed board.
(Appendix 9)

A method of manufacturing the semiconductor device according to Appendix 7 or 8, the method comprising mounting the printed board above the semiconductor element in the case and then filling the case with the sealing material.

While the disclosure has been shown and described in detail, the foregoing description is in all aspects illustrative and not restrictive. It is therefore understood that numerous modifications and variations can be devised.

What is claimed is:

1. A semiconductor device comprising:
a semiconductor element;
a case having an opening and accommodating the semiconductor element;
a signal terminal provided on an inner wall of the case;
a printed board disposed above the semiconductor element in the case by the signal terminal; and
a lid that closes the opening of the case,
wherein the semiconductor element and the signal terminal are electrically connected by a wire,
the wire is curved upward, and
a top portion of the wire is in contact with a back surface of the printed board.

2. The semiconductor device according to claim 1, wherein
the semiconductor device comprises a plurality of the wires, and
the top portion of each of the wires is in contact with the back surface of the printed board.

3. The semiconductor device according to claim 1, wherein
the wires are curved in a corrugated shape, and
a plurality of the top portions of the wires are in contact with the back surface of the printed board.

4. The semiconductor device according to claim 1, further comprising a support wire that supports the top portion of the wire from below.

5. The semiconductor device according to claim 1, wherein a portion of the printed board with which the top portion of the wire is in contact has a same potential as the wire.

6. The semiconductor device according to claim 1, wherein the wire includes a ribbon wire.

7. A semiconductor device comprising:
a semiconductor element;
a case having an opening and accommodating the semiconductor element;
a signal terminal provided on an inner wall of the case;
a printed board disposed above the semiconductor element in the case by the signal terminal;
a sealing material that seals the semiconductor element in the case; and
a lid that closes the opening of the case,
wherein the sealing material is in contact with the printed board.

8. The semiconductor device according to claim 7, wherein the sealing material is in contact with only a back surface side of the printed board.

9. A method of manufacturing the semiconductor device according to claim 7, the method comprising mounting the printed board above the semiconductor element in the case and then filling the case with the sealing material.
